(19) United States
(12) Patent Application Publication
(10) Pub. No.: US 2017/0236393 A1
(43) Pub. Date: Aug. 17, 2017

(54) METHOD AND SYSTEM FOR MONITORING A PORTABLE ARTICLE

(71) Applicant: Se-Kure Controls, Inc., Franklin Park, IL (US)

(72) Inventors: Roger J. Leyden, Inverness, IL (US); David M. Adams, Stone Park, IL (US)

(21) Appl. No.: 15/426,509

(22) Filed: Feb. 7, 2017

Related U.S. Application Data
(60) Provisional application No. 62/294,610, filed on Feb. 12, 2016.

(51) Int. Cl. G08B 13/14; H05K 5/02

(52) U.S. Cl. CPC G08B 13/1436; H05K 5/0204; G08B 13/1445; G08B 21/0261

(57) ABSTRACT

A system for monitoring a portable article having: a housing; a location signal generator on the housing configured to continuously generate location signals that can be processed to monitor a location of the housing; and a securing assembly configured to: a) maintain the housing in an operative state on a portable article being monitored; and b) generate an alert signal in the event that the securing assembly is altered with the housing in the operative state in a manner that allows separation of the housing from a portable article being monitored.

### BACKGROUND OF THE INVENTION

Field of the Invention

This invention relates to security systems for portable articles and, more particularly, to a system that can be secured to a portable article to track the location thereof.

Background Art

It is known to provide systems on portable articles that generate signals continuously that can be monitored to track the location of the articles, as within a business in which the articles are displayed. One such category of system is identified commonly as a “beacon”. These systems can be designed so that a detectable alarm is generated in the event that the article with the associated system is moved outside of a certain predetermined area.

These systems are commonly associated with articles such that would-be thieves might be able to separate the system from the article and thereby abscond with the article without detection. For example, the system might be placed loosely within a purse or another type of monitored article that has a suitable receptacle. Alternatively, the system might be secured inside or outside of an article through a mechanical-type connection, such as a mechanical clasp, or an adhesive, that might be defeated to separate the system from the article without detection.

With an increasing number of expensive, portable articles being displayed, and accessible to be handled by potential purchasers, the need for better, affordable and reliable security systems remains pressing.

### SUMMARY OF THE INVENTION

In one form, the invention is directed to a system for monitoring a portable article. The system includes: a housing; a location signal generator on the housing configured to continuously generate location signals that can be processed to monitor a location of the housing: and a securing assembly configured to: a) maintain the housing in an operative state on a portable article being monitored; and b) generate an alert signal in the event that the securing assembly is altered with the housing in the operative state in a manner that allows separation of the housing from a portable article being monitored.

In one form, the securing assembly has a tether that in conjunction with the housing extends fully around a part of a portable article being monitored with the housing in its operative state.

In one form, the securing assembly has a tether that extends fully around a part of an article being monitored with the housing in its operative state.

In one form, the securing assembly has a tether that defines at least a part of an electrical circuit path. The securing assembly is configured to generate the alert signal in the event that the electrical circuit path is interrupted.

In one form, the system further includes a detectable alarm generator that is activated in the event that the housing is moved outside of a predetermined area.

In one form, the system further includes a detectable alarm generator that is activated by the alert signal.

In one form, the location signal generator is part of a first electrical circuit. The tether has a first state wherein the circuit path is disconnected from the first electrical circuit and a second state wherein the circuit path is integrated into the first electrical circuit.

In one form, the location signal generator has on and off states. The system further includes a detectable alarm generator that is activated in response to the alert signal as an incident of the electrical circuit path being interrupted by one of: a) severance of the tether; and b) changing of the tether from the second state into the first state with the location signal generator in its on state.

In one form, there are releasable connectors that cooperate between the tether and housing to allow the tether to be releasably: a) mechanically connected to the housing; and b) electrically connected to the first electrical circuit by integrating the circuit path into the first electrical circuit.

In one form, the releasable connectors are configured to be snap-connected to each other.

In one form, the system further includes a detectable alarm generator and a motion sensor that is configured to cause the detectable alarm generator to be activated upon a predetermined movement of the housing.

In one form, the system further includes a Bluetooth module capable of communicating with a software operated device.

In one form, the location signal generator has on and off states. The system is configured so that the location signal generator can be selectively changed between its on and off states by a remotely situated software operated device.

In one form, the invention is provided in combination with a software operated device capable of communicating with the Bluetooth module remotely from the housing.

In one form, the system is configured so that the location signal can be processed by a remotely situated software operated device to allow tracking of a location of the housing.

In one form, the tether is in the form of a flexible cord.

In one form, the invention is directed to a method of monitoring a portable article including the steps of: obtaining the system for monitoring a portable article as described above; with the housing in its operative state on a first portable article and the location signal generator in its off state, changing the tether from its first state into its second state; with the tether changed into its second state, changing the location signal generator from its off state into its on state; and monitoring the first portable article using the system.

In one form, the step of monitoring the first portable article consists of monitoring at least one of; a) a location of the housing; and b) the state of the tether.

In one form, the step of monitoring the first portable article includes monitoring the first portable article from a location remote from the first portable article.

In one form, the step of changing the tether from its first state into its second state includes directing the tether through a fully surrounded opening in the first portable article before the tether is changed from its first state into its second state.

### BRIEF DESCRIPTION OF THE DRAWINGS

FIG. 1 is a schematic representation of a system for monitoring a portable article, according to the invention;

FIG. 2 is a schematic representation showing further details of a housing and securing assembly making up part of the system in FIG. 1;

FIG. 3 is a schematic representation of the housing and showing additional details thereof;

FIG. 4 is a schematic representation of electrical connecting structure between the housing and a tether on the inventive system;

FIG. 5 is a schematic representation of a modified form of housing, according to the invention;

FIG. 6 is a schematic representation of a modified form of system, according to the invention;

FIG. 7 is an elevated perspective view of one exemplary form of the inventive system in relationship to an article of the type that can be monitored utilizing the system; and

FIG. 8 is a flow diagram representation of a method of monitoring a portable article utilizing the inventive system.

### DETAILED DESCRIPTION OF THE PREFERRED EMBODIMENT

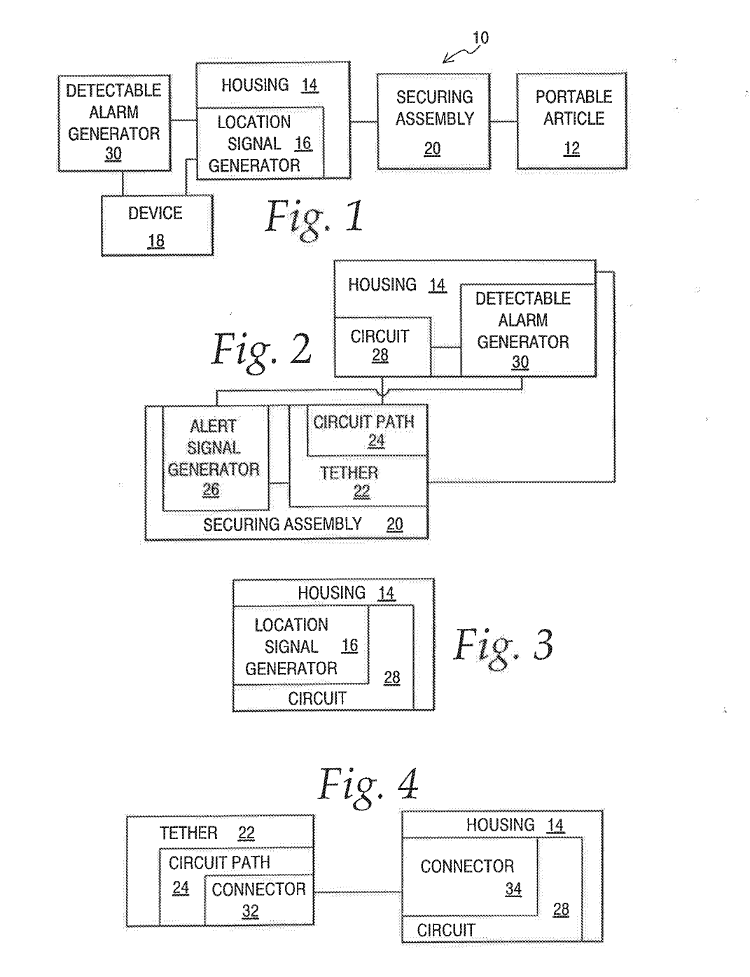

In FIG. 1, a system is shown at 10 for monitoring a portable article 12. The system consists of a housing 14 with a location signal generator 16 thereon configured to continuously generate location signals that can be processed by a device 18 to monitor a location of the housing 14.

A securing assembly 20 is configured to: a) maintain the housing 14 in an operative state on the portable article 12 being monitored; and b) generate an alert signal in the event that the securing assembly 20 is altered with the housing 14 in the operative state in a manner so as to allow separation of the housing from the portable article 12.

As shown in FIG. 2, the securing assembly 20 uses a tether 22 that mechanically facilitates maintaining of the housing 14 in its operative state on the portable article 12. The tether 22 also defines at least part of an electrical circuit path 24.

The securing assembly 20 has an associated signal generator 26 that generates an alert signal in the event that the circuit path 24, which is electrically connected to a circuit 28 on the housing 14, is interrupted. As one example, the circuit path 24 may be defined by a single wire through which a milliamp current is generated.

The invention also contemplates that the circuit path 24 may define a continuous circuit independent of the circuit 28.

As shown in FIG. 1, the device 18 that senses the continuously generated location signals from the generator 16 causes activation of a detectable alarm generator 30, as in the event the housing 14 is moved outside of a predetermined area. The detectable alarm generator 30 may be separate from and/or spaced from the housing 14 or, as shown in FIG. 2, integrated into the housing 14.

The alert signal generator 26 may cause the detectable alarm generator 30 to generate an alarm in the event that the tether 22 is compromised or the continuity of the circuit path 24 and circuit 28 is otherwise interrupted, as hereinbelow described. The nature of the generated alarm is not limited and may be audible, visible, etc.

In one form, as shown in FIG. 3, the location signal generator 16 is part of the circuit 28 on the housing 14.

The tether 22 has a first state wherein the circuit path 24 is disconnected from the circuit 28, and a second state wherein the circuit path 28 is integrated into the circuit 28.

In one form, as shown in FIG. 4, there are releasable connectors 32, 34, respectively associated with the tether 22 and housing 14. The connectors 32, 34 allow releasable mechanical connection between the tether 22 and housing 14. The connectors 32, 34 also allow releasable electrical connection between the tether circuit path 24 and the circuit 28.

Accordingly, the detectable alarm generator 30 is activated in response to an alert signal that is generated as an incident of the circuit path 24 being interrupted by either separation of the connectors 32, 34 or severance of the tether 22 so as to interrupt the circuit path 24. Separate alarm generators might be provided in association with the location signal generator 16 and the alert signal generator 26.

The connectors 32, 34 may be any known type of releasable connector. In one preferred form, the connectors 32, 34 are configured to be snap-connected to each other.

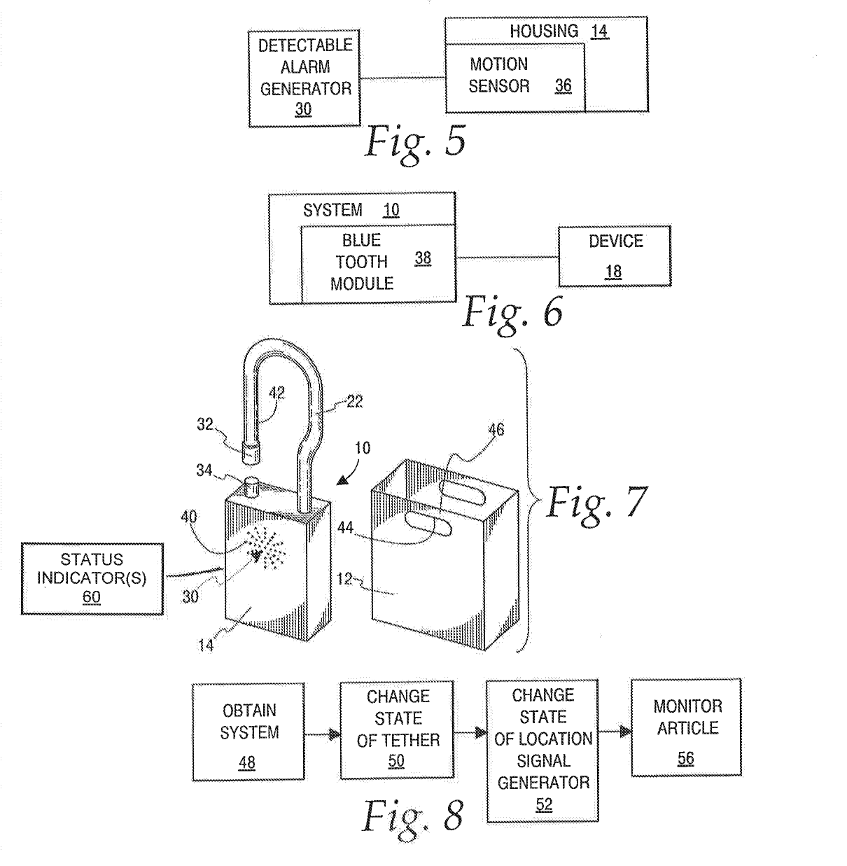

In another form, as shown in FIG. 5, the housing 14 may have an associated motion sensor 36 configured to cause the detectable alarm generator 30, or a separate generator, to be activated upon a predetermined movement of the housing 14.

As shown in FIG. 6, the system 10 may incorporate a low energy Bluetooth module 38 capable of communicating with the device 18 that is preferably any known type of software operated device. The device 18 may be a computer, a cell phone, etc.

With this construction, the location signal generator may be selectively controlled to be placed either in its on or off states through the device 18, either from on site or at a remote location.

Through the device 18, the location signal developed by the generator 16 can be monitored to allow tracking of the housing 14.

The housing 14 can have many different constructions. Likewise, the tether 22 has potentially myriad different constructions. In FIG. 7, an exemplary form of the system 10 is shown in relationship to the portable article 12 in the form of a bag or purse. The depicted housing 14 has a generally squared shape within which the various operating components are contained—including the alarm generator 30 which in this case is designed to generate an audible signal that projects through openings 40 in the housing 14.

The tether 22 is shown as a flexible cord with the connector 32 at one end that can be releasably joined to the housing 14 through the connector 34 to complete an electrical assembly including the circuit path 24 integrated into the circuit 28 within the housing 14. The tether 22 could alternatively have a fixed shape.

With this arrangement, the tether free end 42 can be directed through a fully surrounded opening 44 in the purse 12 to be wrapped around a handle 46. A fully surrounded capturing arrangement can be formed by the tether 22 being wrapped continuously by itself or may be formed by the combined tether 22 and housing 14 shapes.

With the above-described system, monitoring of the portable article can be carried out as shown in flow diagram form in FIG. 8.

As shown at block 48, the inventive system is obtained.

As shown at block 50, with the housing in its operative state on the portable article and the location signal generated in its off state, the tether is changed from its first state into its second state.

As shown at block 52, with the location signal generator in its second state, the location signal generator is changed from its off state into its on state.

As shown at block 56, the portable article is thereafter monitored.

The monitoring may include the location of the housing and/or the state of the tether.

The monitoring can be conducted from an on site location or from a remote location.

Monitoring can be conducted through, or without, a separate device. If a device is used, the various functions of the system 10 can be controlled, and/or observed, as by using an app on a computer, cell phone, or any device capable of running specific software. As just one example, the system operator may use a cell phone to change the location signal generator 30 into the off state to incorporate the function of the tether 22.

The system 10 might be used with or without the tether 22 mechanically connected to an article. Alternatively, the system 10 might be set up so that the tether mechanically secures the housing 14 to an article but without electrical connection of the tether 22.

As shown in FIG. 7, the housing may incorporate one or more visual status indicators 60, such as LEDs. Different LEDs, and coordinated illumination, may be effected to assist system operators and alert customers of active security.

The foregoing disclosure of specific embodiments is intended to be illustrative of the broad concepts comprehended by the invention.

1. A system for monitoring a portable article, the system comprising:
a housing;
a location signal generator on the housing configured to continuously generate location signals that can be processed to monitor a location of the housing; and
a securing assembly configured to: a) maintain the housing in an operative state on a portable article being monitored; and b) generate an alert signal in the event that the securing assembly is altered with the housing in the operative state in a manner that allows separation of the housing from a portable article being monitored.

2. The system for monitoring a portable article according to claim 1 wherein the securing assembly comprises a tether that in conjunction with the housing extends fully around a part of a portable article being monitored with the housing in its operative state.

3. The system for monitoring a portable article according to claim 1 wherein the securing assembly comprises a tether that extends fully around a part of an article being monitored with the housing in its operative state.

4. The system for monitoring a portable article according to claim 1 wherein the securing assembly comprises a tether that defines at least a part of an electrical circuit path, and the securing assembly is configured to generate the alert signal in the event that the electrical circuit path is interrupted.

5. The system for monitoring a portable article according to claim 1 wherein the system further comprises a detectable alarm generator that is activated in the event that the housing is moved outside of a predetermined area.

6. The system for monitoring a portable article according to claim 1 wherein the system further comprises a detectable alarm generator that is activated by the alert signal.

7. The system for monitoring a portable article according to claim 4 wherein the location signal generator is part of a first electrical circuit and the tether has a first state wherein the circuit path is disconnected from the first electrical circuit and a second state wherein the circuit path is integrated into the first electrical circuit.

8. The system for monitoring a portable article according to claim 7 wherein the location signal generator has on and off states and the system further comprises a detectable alarm generator that is activated in response to the alert signal as an incident of the electrical circuit path being interrupted by one of; a) severance of the tether; and b) changing of the tether from the second state into the first state with the location signal generator in its on state.

9. The system for monitoring a portable article according to claim 8 wherein there are releasable connectors that cooperate between the tether and housing to allow the tether to be releasably: a) mechanically connected to the housing; and b) electrically connected to the first electrical circuit by integrating the circuit path into the first electrical circuit.

10. The system for monitoring a portable article according to claim 9 wherein the releasable connectors are configured to be snap-connected to each other.

11. The system for monitoring a portable article according to claim 1 wherein the system further comprises a detectable alarm generator and a motion sensor that is configured to cause the detectable alarm generator to be activated upon a predetermined movement of the housing.

12. The system for monitoring a portable article according to claim 1 wherein the system further comprises a Bluetooth module capable of communicating with a software operated device.

13. The system for monitoring a portable article according to claim 12 wherein the location signal generator has on and off states and the system is configured so that the location signal generator can be selectively changed between its on and off states by a remotely situated software operated device.

14. The system for monitoring a portable article according to claim 12 in combination with a software operated device capable of communicating with the Bluetooth module remotely from the housing.

15. The system for monitoring a portable article according to claim 12 wherein the system is configured so that the location signal can be processed by a remotely situated software operated device to allow tracking of a location of the housing.

16. The system for monitoring a portable article according to claim 4 wherein the tether is in the form of a flexible cord.

17. A method of monitoring a portable article comprising the steps of:
obtaining the system for monitoring a portable article in claim 8;
with the housing in its operative state on a first portable article and the location signal generator in its off state, changing the tether from its first state into its second state;
with the tether changed into its second state, changing the location signal generator from its off state into its on state; and
monitoring the first portable article using the system.

18. The method of monitoring a portable article according to claim 17 wherein the step of monitoring the first portable article comprises monitoring at least one of: a) a location of the housing; and b) the state of the tether.

19. The method of monitoring a portable article according to claim 18 wherein the step of monitoring the first portable article comprises monitoring the first portable article from a location remote from the first portable article.

20. The method of monitoring a portable article according to claim 19 wherein the step of changing the tether from its first state into its second state comprises directing the tether through a fully surrounded opening in the first portable article before the tether is changed from its first state into its second state.
